(19) United States
(12) Patent Application Publication
(10) Pub. No.: US 2003/0015139 A1
(43) Pub. Date: Jan. 23, 2003

(54) Protective packaging

(75) Inventors: Martin G. Afflerbaugh, Austin, TX (US); Patrick C. Howard, Austin, TX (US)

Correspondence Address: Attention: Alan Ball, Office of Intellectual Property Counsel, 3M Innovative Properties Company, P.O. Box 33427, St. Paul, MN, 55133-3427, US

(73) Assignee: 3M Innovative Properties Company

(21) Appl. No.: 09/907,406

(22) Filed: Jul. 17, 2001

(51) Int. Cl. C23C 16/00

(52) U.S. Cl. 118/721; 118/728; 118/720; 118/500; 118/504; 118/505

(57) ABSTRACT

A protective package comprises an enclosure including a back plate that has a base, a top, a first sidewall and a second sidewall mounted thereon to form a cavity including an opening opposite the back plate. A plurality of filament positioning frames occupy the cavity to provide an organized distribution. Each of the filament positioning frames comprises a filament container having a filament clamp, in spaced-apart relationship from the filament container for gripping a plurality of filaments providing a plurality of filament tips extending from each filament clamp. Each of the filament positioning frames further comprises a frame between the filament container and the filament clamp. The frame has a first frame member parallel to a second frame member attached to the filament clamp with each of the plurality of filament tips located adjacent to the opening. A connecting structure attaches the protective package to a coating source to facilitate application of coating material to exposed tips of the filaments.

### FIELD OF THE INVENTION

The invention relates to protective packaging of filamentary material to prevent damage during transit and more particularly to a housing for a plurality of filament organizers to precisely position bare filament tips adjacent to a source of material used to cover the filament tips.

### BACKGROUND OF THE INVENTION

Glass has been used for centuries as a material for controlling and modifying the properties of light beams. A recent and rapidly expanding application of the light modifying properties of glass structures involves the drawing of fine filaments of highly purified glass, more commonly referred to as optical fibers, that direct light signals between light transmitting and receiving locations. The use of optical fiber communication networks has grown to provide an alternative to coaxial cable systems. Advantages provided by optical fiber communications networks include lower cost, the use of fewer signal repeaters for correcting signal distortion, and a higher signal carrying capacity than coaxial cable networks.

Interconnection of fiber optic networks requires high precision devices in the form of optical connectors that join optical fibers to peripheral equipment and other optical fibers while maintaining adequate signal strength. In operation, an optical connector centers the small fiber so that the light gathering core lies directly over and in alignment with a light transmitting source or another fiber. Following correct positioning of an optical fiber, known connecting structures such as crimped connections, soldered connections, spliced connections and the like may be used to maintain alignment between sections of optical fiber.

Soldered connections, in the form of optical fiber splices, terminations and hermetic seals, may include a thin metallic layer over the surface of an optical fiber adjacent to the position at which the splice, termination or seal will be made. Metal coating of terminal ends of optical fibers facilitates solder bonding of connectors before connection of one optical fiber to another optical fiber or related device.

United States Patent, U.S. Pat. No. 4,033,668 describes a method for joining a first glass member, such as an optical fiber, to a second member by means of solderable splices and terminations, which additionally can form hermetic seals. The splice, termination or seal may be formed after coating the peripheral surface of the glass member with a thin adhering metallic layer. After properly positioning the coated glass member, formation of a splice termination or seal with a corresponding member, may use heated solder to flow around the joint to form a bond between the members when cooled. When the second member is also formed of glass, a thin adhering metallic layer, similarly formed on the peripheral surface thereof, provides a solder receptive surface in the area of the intended joint. Metal may be applied to terminal portions of e.g. optical fibers by dipping them into a paste containing conductive metal particles.

United States Patent U.S. Pat. No. 5,100,507 addresses finishing techniques for lensed optical fibers. The process of finishing an optical fiber places an integral lens and a metallized outer coating on the end of an optical fiber. Metal may be deposited on the ends of optical fibers using known sputtering techniques. Materials deposited in this way include titanium, platinum and gold. Application of metal close to the lensed end of an optical fiber allows the formation of a soldered connection very close to the tip of the fiber. This limits subsequent movement of a lensed fiber relative to an aligned optical device.

Prior description of soldered connections involves individual processing of metallized ends of optical fibers. Optical fiber handling represents a challenge for the optical fiber industry. Manufacturing operations may include a number of steps requiring handling of long and short lengths of optical fiber. These lengths of optical fiber are fragile filaments requiring careful handling using more efficient processes to accelerate the production of optical fibers for communication links and related devices. With a growing demand for optical fiber systems and devices, there is a need for processing a plurality of optical fibers simultaneously.

Accompanying the need for simultaneously processing a large number of individual components is the trend towards concentration of manufacturing operations to take advantage of specialist capabilities. This trend necessitates transferal of components, representing work in progress, between manufacturing sites. Such transfer of work in progress may only be possible using transportation equipment that not only contains but also protects partially completed components from damage, particularly when the contents of a container include fragile structures such as optical fibers. For convenient processing, there is a need for a transportation container to organize multiple optical fibers to facilitate component treatment for device manufacture.

### SUMMARY OF THE INVENTION

The present invention provides a protective enclosure, designed to organize a large number of optical fibers having their tips exposed to receive a coating of selected materials, such as metals and metal oxides that may be applied using vapor deposition techniques. A protective enclosure according to the present invention is vacuum compatible for direct attachment to vapor deposition equipment to precisely position bare fiber tips adjacent to vacuum deposition sources. The enclosure includes planar elements, also referred to herein as witness plates. During application of material to the ends of optical fibers the material also settles on the witness plates. The thickness of the deposit on the witness plates provides a measure corresponding to the thickness of material covering the tips of treated optical fibers.

Protective enclosures for filaments, according to the present invention, satisfy a number of requirements related to the placement of substantially uncontaminated material, preferably an antireflective coating of a metal oxide, or related known material, to provide filaments or fibers having coated tips. One requirement is the protection of filaments during shipping to and from different processing locations. An enclosure cover provides environmental protection, once the filaments have been suitably organized within the protective enclosure. The cover prevents damage to exposed filament tips of coils that reside in filament organizers suitably sized to fit into compartments formed within a protective enclosure. After installation of filament organizers into a protective enclosure, there is no need for further handling of either the filament organizers, or the or the exposed filament tips extending from them, until the process of material deposition is complete. Reduction in filament handling is accomplished effectively by designing the protective enclosure as a “plug-in” unit for suitable attachment to a vapor deposition coater. This places rows of filament tips inside a vapor deposition chamber for controlled application of material around the exposed filament tips.

More particularly, the present invention provides a protective package comprising an enclosure having a cavity including an opening. A plurality of filament positioning frames fit in the cavity to provide an organized distribution of filament positioning frames. Each filament positioning frame has a filament clamp to grip a plurality of filaments to provide a plurality of filament tips extending from each of the plurality of filament clamps located adjacent to the opening.

The present invention also provides a fixture used for positioning exposed tips of filaments to receive a coating. Such a fixture comprises an enclosure including a back plate that has a base, a top, a first sidewall and a second sidewall mounted thereon to form a cavity including an opening opposite the back plate. A plurality of filament positioning frames occupy the cavity to provide an organized distribution. Each of the filament positioning frames comprises a filament container having a filament clamp, in spaced-apart relationship from the filament container for gripping a plurality of filaments providing a plurality of filament tips extending from each filament clamp. Each of the filament positioning frames further comprises a frame between the filament container and the filament clamp. The frame has a first frame member parallel to a second frame member attached to the filament clamp with each of the plurality of filament tips located adjacent to the opening. A connecting structure attaches the fixture to a coating source such that the exposed tips of filaments receive a covering of coating material.

Definitions

For clarification, the following definitions provide the meaning of terms that may be used throughout this specification.

The term “filament” refers thread-like structures preferably ceramic structures, particularly optical fibers.

Use of the terms “coating” or “deposit” herein refers to application of selected materials, including metals and metal oxides, to filament surfaces using any of a variety of methods of application, preferably vacuum coating or deposition. Coatings and deposits include known materials that provide antireflective coatings.

A “filament container” may include one or more “filament holders” in the form of substantially planar envelopes or pouches each holding a single filament. A stack of holders satisfies the definition of a container according to the present invention.

The beneficial effects described above apply generally to the exemplary devices and mechanisms disclosed herein of the protective enclosure for filaments, particularly optical fibers. The specific structures through which these benefits are delivered will be described in detail hereinbelow.

### BRIEF DESCRIPTION OF THE DRAWINGS

The invention will now be described in greater detail in the following way of example only and with reference to the attached drawings in which:

FIG. 1 is a perspective view representative of an apparatus according to the present invention for holding filaments in a prescribed spatial relationship.

FIG. 2 is a perspective view to provide detail of upper and lower gripping plates of the apparatus used to hold filaments.

FIG. 3 shows a perspective view of a schematic diagram of a plurality of filament-positioning frames enclosed in a protective enclosure that is used as a transporter for fragile filaments.

FIG. 4 perspective view of a protective enclosure including a protective cover that prevents damage during transportation of fragile filaments.

FIG. 5 provides perspective view including a cutaway portion to show the packing of filament positioning frames inside a protective enclosure according to the present invention.

FIG. 6 shows a partially cutaway perspective view of a protective enclosure designed to transport fewer filament positioning frames than the enclosure shown in FIG. 5.

### DETAILED DESCRIPTION OF THE PREFERRED EMBODIMENTS

As required, detailed embodiments of the present invention are disclosed herein; however, it is to be understood that the disclosed embodiments are merely exemplary of the invention that may be embodied in various and alternative forms. The figures are not necessarily to scale, some features may be exaggerated or minimized to show details of particular components. Therefore, specific structural and functional details disclosed herein are not to be interpreted as limiting, but merely as a basis for the claims and as a representative basis for teaching one skilled in the art to variously employ the present invention.

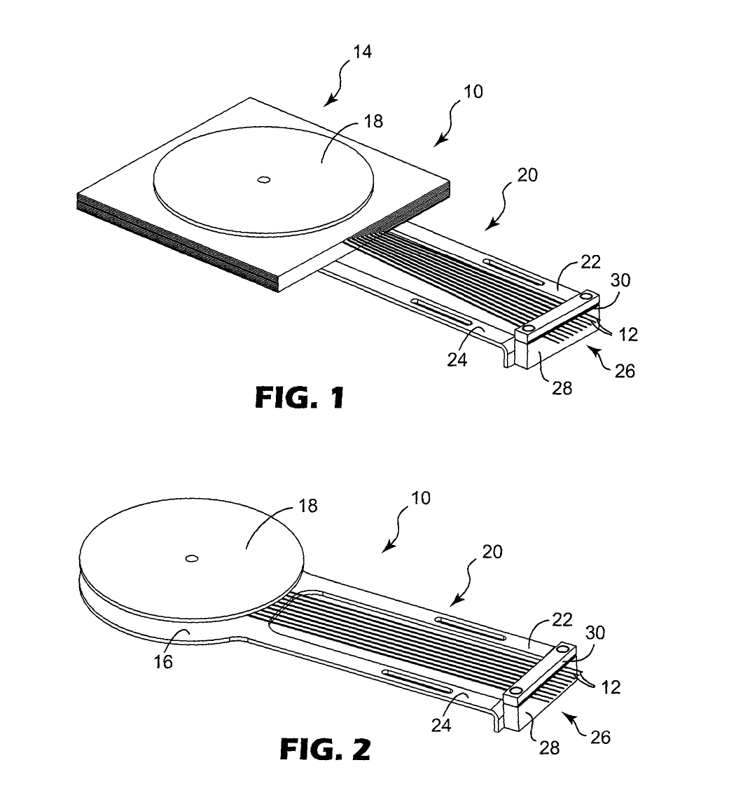

Referring now to the figures wherein like numbers identify like parts throughout the several views, FIG. 1 provides a schematic perspective view of an apparatus, also referred to herein as a filament-positioning frame 10 according to the present invention. The filament-positioning frame 10 provides a means for organizing a plurality of filaments 12 preferably in the form of optical fibers. Each of the filaments 12 extends from a coil of filament (not shown) conveniently stored in a container, usually in the form of a plastic pouch or envelope. As indicated in FIG. 1, the filament-positioning frame 10 accommodates more than a single filament 12 requiring placement of multiple containers in the form of a stack of pouches 14. A stack of pouches 14 may be attached to the filament-positioning frame 10 using a first gripping plate 16 (not shown) and a second gripping plate 18 on either side of the stack of pouches 14. The gripping plates 16,18 may be secured to one end of an organizing frame 20 that includes a first longitudinal frame member 22 and a second longitudinal frame member 24, which are in a parallel, spaced-apart relationship. A filament clamp 26 also forms part of the organizing frame 20 to provide coupling of longitudinal frame members 22,24 so that they maintain their parallel relationship. The filament clamp 26 includes a support 28 for the plurality of filaments 12 extending from the stack of pouches 14. A retention clamp 30 engages the support 28 to capture the filaments 12 therebetween, to hold them in a prescribed spatial relationship relative to each other. Preferably the filaments 12, extending from a filament clamp 26 are of essentially the same length.

FIG. 2 shows a preferred embodiment of a filament positioning frame 10 according to the present invention to clarify the construction and attachment of the first gripping plate 16. As shown, the first gripping plate 16 is an integral portion of the structure of the organizing frame 20. This structure is not to be viewed as limiting since it is conceivable to use other means for positioning and coupling a first gripping plate 16 to an organizing frame 20. The view of FIG. 2 omits containers 14 of optical fibers 12 to indicate the relationship between the first gripping plate 16 and the second gripping plate 18. Illustration of a plurality of filaments 12 shows the relationship of this parallel array to the first and second frame members 22, 24 and the extension of the ends of the filaments 12 beyond the filament clamp 26.

FIG. 3 provides a perspective view of a protective enclosure 100 that includes a top 102, a base 104, a back plate 106, a first side wall 108 and a second side wall 110. The enclosure 100 opens to the front to reveal filament positioning frames 10 in an organized arrangement, usually stacked one upon another. Preferably, the filament clamps 26 of the filament positioning frames 10 extend out from the enclosure 100 presenting a number of filament tips 112 to receive a coating of material from a suitable material source. A vapor deposition chamber provides a preferred source of coating material.

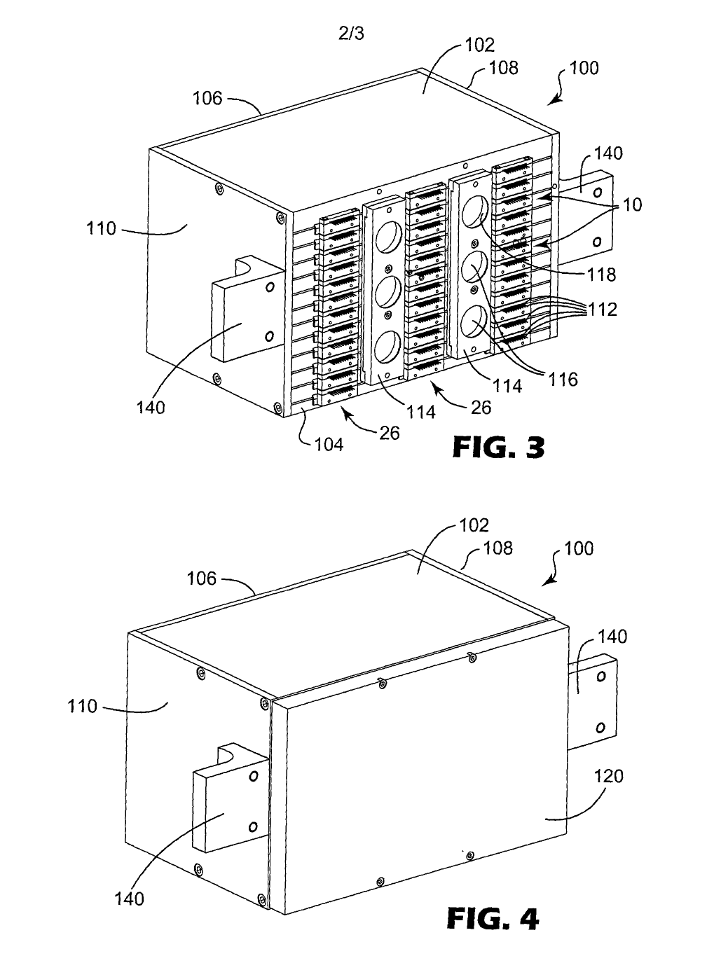

One or more holders 114 of deposition indicators 116, also referred to herein as witness plates, may be attached to the protective enclosure 100. The deposition indicators 116 occupy a position in a substantially common plane with the filament tips 112 extending from filament clamps 26. This positioning allows the deposition indicators 116 to receive coating material from a nearby coating source in an amount similar to that deposited on filament tips 112. Thereafter, inspection of a deposition indicator 116 reveals the amount and quality of coverage of coating material on the deposition indicator 116 and adjacent filament tips 112. A deposition indicator 116 usually takes the form of a glass plate sized to fit in an opening 118 formed in a holder 114. Control of the amount of coating or deposit applied to filament tips 112, using vapor deposition techniques, preferably requires a calibration run of the coating equipment to in the presence of at least one deposition indicator. The results of the calibration run provide the basis for advisable equipment operating conditions during the process of coating filament tips. After assembly of filament positioning frames 10 and holders 114 with a protective enclosure 100, the filament tips 112 may be protected from damage by attaching a detachable cover 120, as shown in FIG. 4. The detachable cover 120 includes a recess that allows enough internal space to prevent any part of the cover 120 from touching the filament tips 112 protruding from the protective enclosure 100. A detachable cover 120 may be attached to a protective enclosure 100 by one of any number of commonly used means for removably attaching one part to another. Protective enclosures 100 and detachable covers 120 according to the present invention may be adapted to use attachment means including, but not limited to, hinges, clamps and bolts and the like.

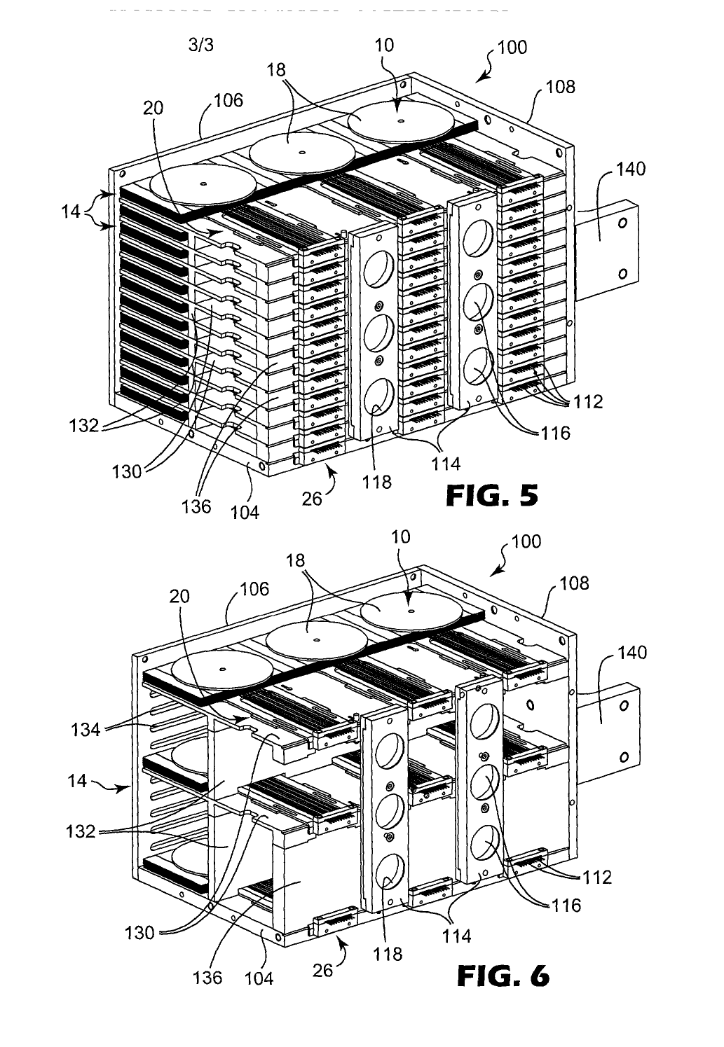

FIG. 5 shows a partially cut-away perspective view of a protective enclosure 100 having its top 102 and second side 110 removed to reveal shelves 130 for supporting filament positioning frames 10 according to the present invention. Internal separators 132 maintain sufficient space between individual shelves 130 for convenient stacking of a plurality of filament positioning frames 10. Each shelf 130 includes a faceplate 136. The faceplates 136 contact each other to prevent passage of coating material behind them during attachment of a protective enclosure 100, according to the present invention, that becomes a fixture to a source of coating material, preferably a vapor deposition chamber.

FIG. 6 provides a similar, partially cutaway perspective view to FIG. 5, and shows an alternative embodiment of a protective enclosure 100 according to the present invention. In this case a protective enclosure 100 accommodates fewer filament positioning frames 10 requiring an increase in the size of internal separators 132 and faceplates 136 between the shelves supporting the filament positioning frames 10. In the preferred embodiment shown in FIG. 6, the back plate 106 includes ventilation slots 134 to exhaust air during vacuum deposition of materials.

With the illustrated arrangement of filament positioning frames 10 in FIG. 5 and FIG. 6, each filament-positioning frame occupies one of a number of compartments inside the protective enclosure 100. Precise positioning of each filament-positioning frame 10 allows the use of the protective enclosure 100 during treatment of exposed filament tips 112 protruding from the front of a protective enclosure 100. This facilitates a batch process for controlled application of a material, such as a metal oxide deposit, at specified locations. A distinguishing feature of a protective enclosure 100 according to the present invention is the ease with which it may be incorporated into a vacuum deposition process to deposit a layer of metal or metal oxide around the tip 112 of each of a plurality of optical fibers 12. During processing, the cover 120 is removed from the protective enclosure 100 to expose the filament clamps 26 that present filament tips 112 for application of a required deposit. Attachment of a protective enclosure 100 to a source of coating material may use any suitable connection means that will hold the enclosure 100 in place during normal operation of the coating equipment. When the coating equipment provides deposition of coating material, as in vapor deposition, an attachment port is typically available to receive the protective enclosure. Contact between the port and the enclosure 100 may be maintained using a connecting flange 140 or frame.

A protective package for filaments and a fixture for facilitating the coating of filament tips have been described herein. These devices and related variations, which will be appreciated by those skilled in the art, are within the intended scope of this invention as claimed below. As previously stated, detailed embodiments of the present invention are disclosed herein; however, it is to be understood that the disclosed embodiments are merely exemplary of the invention that may be embodied in a variety of forms.

What is claimed is:

1. A protective package comprising:
an enclosure having a cavity formed therein, said cavity including an opening; and
a plurality of filament positioning frames received in said cavity to provide an organized distribution of said plurality of filament positioning frames each having a filament clamp to grip a plurality of filaments to provide a plurality of filament tips extending from each of said plurality of filament clamps located adjacent to said opening.

2. The protective package of claim 1, wherein said enclosure further includes a back plate having a base, a top, a first sidewall and a second sidewall mounted thereon to form said cavity including said opening opposite said back plate.

3. The protective package of claim 1, wherein each said filament positioning frame further comprises a filament container having said filament clamp, in spaced-apart relationship therefrom to grip said plurality of filaments, each said filament positioning frame further including an organizing frame between said filament container and said filament clamp, said frame having a first frame member parallel to a second frame member attached to said filament clamp.

4. A protective package comprising:
an enclosure including a back plate having a base, a top, a first sidewall and a second sidewall mounted thereon to form a cavity including an opening opposite said back plate; and
a plurality of filament positioning frames received in said cavity to provide an organized distribution of said plurality of filament positioning frames each comprising a filament container having a filament clamp, in spaced-apart relationship from said filament container for gripping a plurality of filaments providing a plurality of filament tips extending from each said filament clamp, each of said plurality of filament positioning frames further comprising an organizing frame between said filament container and said filament clamp, said organizing frame having a first frame member parallel to a second frame member attached to said filament clamp, each of said plurality of filament tips located adjacent to said opening.

5. The protective package of claim 4, wherein said cavity is divided into a number of compartments.

6. The protective package of claim 5, wherein each said compartment has a size sufficient for one of said plurality of filament positioning frames.

7. A fixture used for positioning exposed tips of filaments to receive a coating, said fixture comprising:
an enclosure having a cavity formed therein, said cavity including an opening;
a plurality of filament positioning frames received in said cavity to provide an organized distribution of said plurality of filament positioning frames each having a filament clamp to grip a plurality of filaments to provide a plurality of filament tips extending from each of said plurality of filament clamps located adjacent to said opening; and
a connecting structure for attaching said fixture to a coating source such that said exposed tips receive said coating.

8. A fixture used for positioning exposed tips of filaments to receive a coating, said fixture comprising:
an enclosure including a back plate having a base, a top, a first sidewall and a second sidewall mounted thereon to form a cavity including an opening opposite said back plate;
a plurality of filament positioning frames received in said cavity to provide an organized distribution of said plurality of filament positioning frames each comprising a filament container having a filament clamp, in spaced-apart relationship from said filament container for gripping a plurality of filaments providing a plurality of filament tips extending from each said filament clamp, each of said plurality of filament positioning frames further comprising an organizing frame between said filament container and said filament clamp, said organizing frame having a first frame member parallel to a second frame member attached to said filament clamp, each of said plurality of filament tips located adjacent to said opening; and
a connecting structure for attaching said fixture to a coating source such that said exposed tips receive said coating.

9. The fixture of claim 8, further including at least one deposition indicator adjacent to said opening.
